(19) United States
(12) Patent Application Publication
(10) Pub. No.: US 2024/0092816 A1
(43) Pub. Date: Mar. 21, 2024

(54) PRECURSORS CONTAINING FLUORINATED ALKOXIDES AND AMIDES

(71) Applicant: ENTEGRIS, INC., Billerica, MA (US)

(72) Inventors: Drew Michael Hood, Newtown, CT (US); Thomas M. Cameron, Newtown, CT (US)

(21) Appl. No.: 18/240,873

(22) Filed: Aug. 31, 2023

Related U.S. Application Data
(60) Provisional application No. 63/403,390, filed on Sep. 2, 2022.

(51) Int. Cl. C07F 17/00; C07F 7/00; C07F 7/28

(52) U.S. Cl. CPC C07F 17/00; C07F 7/003; C07F 7/28

(57) ABSTRACT

The present disclosure relates to the field of precursors, more specifically precursors containing at least one fluorinated group. In some embodiments, the precursors are hafnium, zirconium, and titanium bis(cyclopentadienyl) precursors containing fluorinated alkoxides and amides. In some embodiments, the present disclosure relates to using precursors for deposition of group 4 containing thin films, such as HfOx, ZrOx, and TiOx film applications. These thin films can be used in a variety of applications including semiconductor device structures. The compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

### FIELD

The present disclosure relates to the field of precursors, more specifically precursors containing at least one fluorinated group.

### BACKGROUND

Thin films can be used with semiconductor device structures.

### SUMMARY

There is a need for new precursors for applications related to 3D-NAND, DRAM, and Logic. As tungsten is replaced by molybdenum in 3D-NAND, a blocking layer is needed to protect the aluminum oxide (Al₂O₃). The present disclosure relates to the field of precursors, more specifically precursors containing at least one fluorinated group. In some embodiments, the precursors are hafnium, zirconium, and titanium bis(cyclopentadienyl) precursors containing fluorinated alkoxides and amides. In some embodiments, the present disclosure relates to using the precursors as described herein for deposition of group 4 containing thin films, such as HfOx, ZrOx, and TiOx film applications. These thin films can be used in a variety of applications including semiconductor device structures. The compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

The precursors of the present disclosure have good stability and volatility. For example, bis(cyclopentadienyl) Hf compounds containing fluorinated ligands can have significantly higher volatility than compounds containing non-fluorinated ligands.

In some embodiments, the compounds are liquid at room temperature.

In some aspects, the techniques described herein relate to a compound including
the following formula:

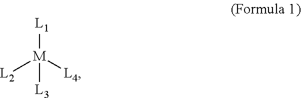

M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; and L₂-L₄ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H

In some aspects, the techniques described herein relate to a compound, wherein the compound has the following formula:

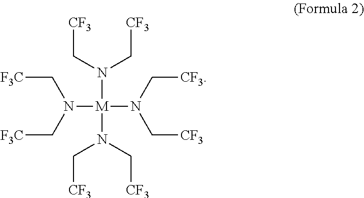

In some aspects, the techniques described herein relate to a compound, wherein L₁-L₄ are each independently 1,1,1,3,3,3-hexafluoro-2-propoxide, 2,2,3,3,4,4,4-Heptafluoro-1-butoxide, or 2,2,2-trifluoroethoxide.

In some aspects, the techniques described herein relate to a compound, wherein L₁-L₄ are trifluoroacetate.

In some aspects, the techniques described herein relate to a compound including the following formula:

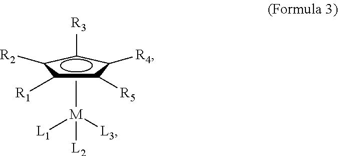

wherein: M is Ti, Zr, or Hf; L₁ is a C₁-C₁₅ fluoroalkyl, C₂-C₁₅ amide containing at least one fluoro group, C₂-C₁₅ carboxylate containing at least one fluoro group, or F; L₂ and L₃ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and R₁-R₅ are each independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H.

In some aspects, the techniques described herein relate to a compound, the compound has the following formula:

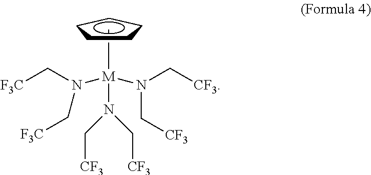

In some aspects, the techniques described herein relate to a compound, wherein R₁-R₅ are H.

In some aspects, the techniques described herein relate to a compound, wherein L₁-L₃ are 1,1,1,3,3,3-hexafluoro-2-propoxide, 2,2,3,3,4,4,4-heptafluoro-1-butoxide, 2,2,2-trifluoroethoxide.

In some aspects, the techniques described herein relate to a compound, wherein L₁-L₃ are trifluoroacetate.

In some aspects, the techniques described herein relate to a compound including the following formula:

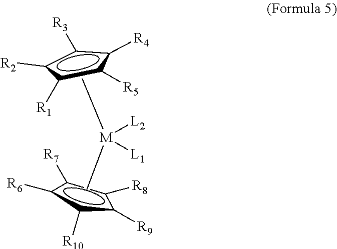

wherein M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and R₁-R₁₀ are each independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H.

In some aspects, the techniques described herein relate to a compound, wherein the compound has the following formula:

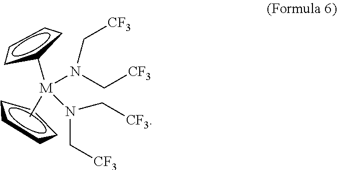

In some aspects, the techniques described herein relate to a compound, wherein R₁-R₁₀ are H.

In some aspects, the techniques described herein relate to a compound, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

In some aspects, the techniques described herein relate to a compound, wherein the compound has the following formula:

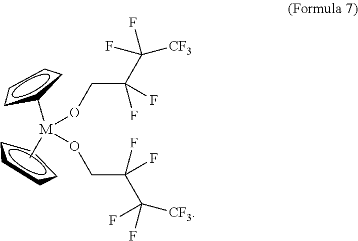

In some aspects, the techniques described herein relate to a compound or claim 12, wherein L₁ and L₂ are 2,2,2-trifluoroethoxide.

In some aspects, the techniques described herein relate to a compound including the following formula:

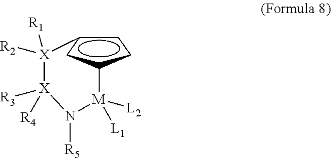

wherein M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; X are each independently C or Si; and R₁-R₅ are each independently a C₁-C₁₅ alkyl, C₁-C₁₅ fluoroalkyl, or H.

In some aspects, the techniques described herein relate to a compound, wherein X are C, R₁-R₄ are H, and R₅ is a methyl.

In some aspects, the techniques described herein relate to a compound, wherein L₁ and L₂ are bis(2,2,2-trifluoroethyl)amido.

In some aspects, the techniques described herein relate to a compound, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

In some aspects, the techniques described herein relate to a compound, wherein L₁ and L₂ are trifluoroacetate.

In some aspects, the techniques described herein relate to a compound including the following formula:

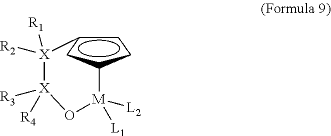

wherein: M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; X are each independently C or Si; and R₁-R₄ are each independently a C₁-C₁₅ alkyl, C₁-C₁₅ fluoroalkyl, or H.

In some aspects, the techniques described herein relate to a compound, wherein X are C, R₁-R₃ are H, and R₄ is a methyl.

In some aspects, the techniques described herein relate to a compound, wherein L₁ and L₂ are bis(2,2,2-trifluoroethyl)amido.

In some aspects, the techniques described herein relate to a compound, wherein L₁ and L₂ are trifluoroacetate.

In some aspects, the techniques described herein relate to a compound, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 displays fluorinated ligand compounds according to the present disclosure, in accordance with some embodiments.

FIG. 2 displays thermogravimetric analysis (TGA) of a nonfluorinated compound: bis(cyclopentadienyl)Hf(NEtMe)₂.

FIG. 3 displays TGA of bis(cyclopentadienyl)Hf(OCH(CF₃)₂)₂, in accordance with some embodiments.

FIG. 4 displays TGA of bis(cyclopentadienyl)Hf(OCH₂CF₃)₂, in accordance with some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “alkyl” refers to a hydrocarbon chain radical having from 1 to 30 carbon atoms. The alkyl may be attached via a single bond. An alkyl having n carbon atoms may be designated as a “Ce alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is saturated (e.g., single bonds). In some embodiments, the alkyl is unsaturated (e.g., double bonds and/or triple bonds). In some embodiments, the alkyl is linear. In some embodiments, the alkyl is branched. In some embodiments, the alkyl is substituted. In some embodiments, the alkyl is unsubstituted. In some embodiments, the alkyl may comprise, consist of, or consist essentially of, or may be selected from the group consisting of, at least one of a C₁-C₁₂ alkyl, a C₁-C₁₁ alkyl, a C₁-C₁₀ alkyl, a C₁-C₉ alkyl, a C₁-C₈ alkyl, a C₁-C₇ alkyl, a C₁-C₆ alkyl, a C₁-C₄ alkyl, a C₁-C₃ alkyl, or any combination thereof. In some embodiments, the alkyl may comprise, consist of, or consist essentially of, or may be selected from the group consisting of, at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, octyl, decyl, dodecyl, octadecyl, or any combination thereof.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or any combination(s) thereof.

As used herein “embedded” means that a first material is distributed throughout a second material.

There is a need for new precursors for applications related to 3D-NAND, DRAM, and Logic. As tungsten is replaced by molybdenum in 3D-NAND, a blocking layer is needed to protect the aluminum oxide (Al₂O₃). The present disclosure relates to the field of precursors, more specifically precursors containing at least one fluorinated group. In some embodiments, the precursors are hafnium, zirconium, and titanium bis(cyclopentadienyl) precursors containing fluorinated alkoxides and amides. In some embodiments, the present disclosure relates to using the precursors as described herein for deposition of group 4 containing thin films, such as HfOx, ZrOx, and TiOx film applications. These thin films can be used in a variety of applications including semiconductor device structures. The compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

The precursors of the present disclosure have good stability and volatility. For example, bis(cyclopentadienyl) Hf compounds containing fluorinated ligands can have significantly higher volatility than compounds containing non-fluorinated ligands.

In some embodiments, the compound of the present disclosure comprises a compound with the following formula:

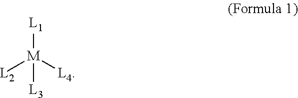

In some embodiments, for Formula 1, M is titanium (Ti), zirconium (Zr), or hafnium (Hf).

In some embodiments, for Formula 1, L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F.

In some embodiments, for Formula 1, L₂-L₄ are each independently an alkyl, amide, alkoxide, carboxylate, amidinate, guanidinate, β-diketonate, β-ketoiminate, β-diketiminate, fluoroalkyl, alkoxide containing at least one fluoro group, amide containing at least one fluoro group, carboxylate containing at least one fluoro group, F, Cl, Br, I, or H. In some embodiments, for Formula 1, L₂-L₄ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H. For example, L₂-L₄ are a C₁-C₁₅ alkyl (e.g., methyl). For example, L₂-L₄ are a C₁-C₁₅ alkyl, where L₂ is methyl, L₃ is ethyl, and L₄ is butyl. For example, L₂ is a C₂-C₁₅ amide, L₃ is a C₁-C₁₅ alkoxide, and L₄ is a C₅-C₁₅ amidinate.

In some embodiments, L₁-L₄ are the same class of ligand (e.g., C₁-C₁₅ alkyl) or the same ligand (e.g., methyl). In some embodiments, L₁-L₄ are the same class of ligand (e.g., C₁-C₁₅ alkyl) but different ligands (e.g., L₁ is methyl, L₂ is ethyl, L₃ is propyl, and L₄ is butyl). In some embodiments, L₁-L₄ are all different classes of ligand (e.g., L₁ is a C₁-C₁₅ alkyl, L₂ is a C₂-C₁₅ amide, L₃ is a C₁-C₁₅ carboxylate, and L₄ is a C₁-C₁₅ alkoxide). In some embodiments, at least one of L₁-L₄ are the same class of ligand (e.g., L₁ and L₂ are C₁-C₁₅ alkyl, L₃ is a C₁-C₁₅ carboxylate, and L₄ is a C₁-C₁₅ alkoxide).

In some embodiments, for Formula 1, L₁-L₄ are C₂-C₁₅ amide containing at least one fluoro group (e.g. bis(2,2,2-trifluoroethyl)amido)). For example, Formula 2 represents the formula for when L₁-L₄ are bis(2,2,2-trifluoroethyl)amido) for Formula 1, as shown below:

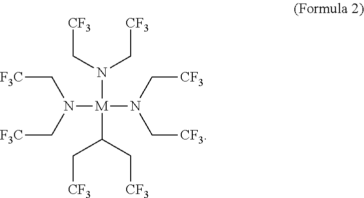

In some embodiments, for Formula 1, L₁-L₄ are each independently 1,1,1,3,3,3-hexafluoro-2-propoxide, 2,2,3,3,4,4,4-Heptafluoro-1-butoxide, or 2,2,2-trifluoroethoxide. For example, in some embodiments, L₁-L₄ are 1,1,1,3,3,3-hexafluoro-2-propoxide, L₁-L₄ 2,2,3,3,4,4,4-Heptafluoro-1-butoxide, 2,2,2-trifluoroethoxide, or combinations thereof.

In some embodiments, for Formula 1, L₁-L₄ are C₂-C₁₅ carboxylate containing at least one fluoro group (e.g., trifluoroacetate).

In some embodiments, the compound of the present disclosure comprises a compound with the following formula:

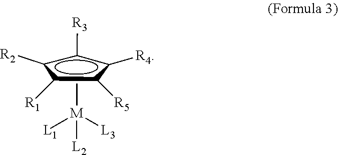

In some embodiments, for Formula 3, M is titanium (Ti), zirconium (Zr), or hafnium (Hf).

In some embodiments, for Formula 3, L₁ is a C₁-C₁₅ fluoroalkyl, C₂-C₁₅ amide containing at least one fluoro group, C₂-C₁₅ carboxylate containing at least one fluoro group, or F.

In some embodiments, for Formula 3, L₂ and L₃ are each independently an alkyl, amide, alkoxide, carboxylate, amidinate, guanidinate, β-diketonate, β-ketoiminate, β-diketiminate, fluoroalkyl, alkoxide containing at least one fluoro group, amide containing at least one fluoro group, carboxylate containing at least one fluoro group, F, Cl, Br, I, or H. In some embodiments, for Formula 3, L₂ and L₃ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

In some embodiments, for Formula 3, L₁-L₃ are the same class of ligand (e.g., C₁-C₁₅ alkyl) or the same ligand (e.g., methyl). In some embodiments, L₁-L₃ are the same class of ligand (e.g., C₁-C₁₅ alkyl) but different ligands (e.g., L₁ is methyl, L₂ is ethyl, and L₃ is propyl). In some embodiments, L₁-L₃ are all different classes of ligand (e.g., L₁ is a C₁-C₁₅ alkyl, L₂ is a C₂-C₁₅ amide, and L₃ is a C₁-C₁₅ carboxylate). In some embodiments, at least one of L₁-L₃ are the same class of ligand (e.g., L₁ and L₂ are C₁-C₁₅ alkyl and L₃ is a C₁-C₁₅ carboxylate).

In some embodiments, for Formula 3, R₁-R₅ are each independently a C₁-C₁₅ alkyl, C₁-C₁₅ ether, C₂-C₁₅ amine, C₁-C₁₅ fluoroether, C₁-C₁₅ fluoroalkyl, OH, F, C₁, Br, I, or H.

In some embodiments, R₁-R₅ are the same class of functional group (e.g., C₁-C₁₅ alkyl) or the same functional group (e.g., methyl). In some embodiments, R₁-R₅ are the same class of functional group (e.g., C₁-C₁₅ alkyl) but different functional groups (e.g., R₁ is methyl, R₂ is ethyl, R₃ is propyl, R₄ is butyl, and R₅ is pentyl). In some embodiments, R₁-R₅ are all different classes of functional group (e.g., R₁ is a C₁-C₁₅ alkyl, R₂ is a C₂-C₁₅ amine, R₃ is a C₁-C₁₅ ether, R₄ is a C₁-C₁₅ fluoroether, and R₅ is H). In some embodiments, at least one of R₁-R₅ are the same class of functional group (e.g., R₁ and R₂ are C₁-C₁₅ alkyl and R₃-R₅ is a C₁-C₁₅ fluoroalkyl).

In some embodiments, for Formula 3, L₁-L₃ are C₂-C₁₅ amide containing at least one fluoro group (e.g., bis(2,2,2-trifluoroethyl)amido). For example, Formula 4 represents the compound for when R₁-R₅ are H and L₁-L₃ are bis(2,2,2-trifluoroethyl)amido for Formula 3, as shown below:

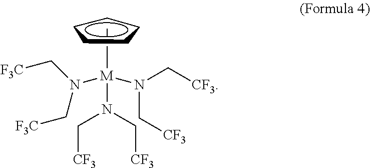

In some embodiments, for Formula 3, R₁-R₅ are H.

In some embodiments, for Formula 3, L₁-L₃ are C₁-C₁₅ alkoxides containing at least one fluoro group (e.g., 1,1,1,3,3,3-hexafluoro-2-propoxide, 2,2,3,3,4,4,4-heptafluoro-1-butoxide, or 2,2,2-trifluoroethoxide). In some embodiments, for Formula 3, R₁-R₅ are H and L₁-L₃ are 1,1,1,3,3,3-hexafluoro-2-propoxide. In some embodiments, for Formula 3, R₁-R₅ are H and L₁-L₃ are 2,2,3,3,4,4,4-heptafluoro-1-butoxide.

In some embodiments, for Formula 3, R₁-R₅ are H and L₁-L₃ are 2,2,2-trifluoroethoxide.

In some embodiments, for Formula 3, L₁-L₃ are a C₂-C₁₅ carboxylate containing at least one fluoro group (e.g., trifluoroacetate). In some embodiments, for Formula 3, R₁-R₅ are H and L₁-L₃ are trifluoroacetate.

In some embodiments, the compound of the present disclosure comprises a compound with the following formula:

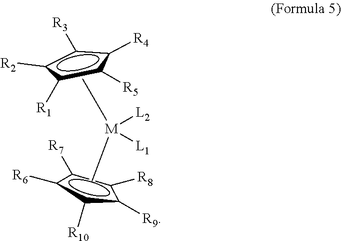

In some embodiments, for Formula 5, M is titanium (Ti), zirconium (Zr), or hafnium (Hf).

In some embodiments, for Formula 5, L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F.

In some embodiments, for Formula 5, L₂ is an alkyl, amide, alkoxide, carboxylate, amidinate, guanidinate, β-diketonate, β-ketoiminate, β-diketiminate, fluoroalkyl, alkoxide containing at least one fluoro group, amide containing at least one fluoro group, carboxylate containing at least one fluoro group, F, Cl, Br, I, or H. In some embodiments, for Formula 5, L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

In some embodiments, for Formula 5, L₁ and L₂ are the same class of functional group (e.g., C₁-C₁₅ alkyl) or the same functional group (e.g., methyl). In some embodiments, L₁ and L₂ are the same class of ligand (e.g., C₁-C₁₅ alkyl) but different ligands (e.g., L₁ is methyl and L₂ is ethyl). In some embodiments, L₁ and L₂ are all different classes of ligands (e.g., L₁ is a C₁-C₁₅ alkyl and L₂ is a C₂-C₁₅ amide).

In some embodiments, for Formula 5, R₁-R₁₀ are each independently a C₁-C₁₅ alkyl, C₁-C₁₅ ether, C₂-C₁₅ amine, C₁-C₁₅ fluoroether, C₁-C₁₅ fluoroalkyl, OH, F, C₁, Br, I, or H.

In some embodiments, R₁-R₁₀ are the same class of functional group (e.g., C₁-C₁₅ alkyl) or the same functional group (e.g., methyl). In some embodiments, R₁-R₁₀ are the same class of functional group (e.g., C₁-C₁₅ alkyl) but different functional groups (e.g., R₁ is methyl, R₂ is ethyl, R₃ is propyl, R₄ is butyl, R₅ is pentyl, etc.). In some embodiments, R₁-R₁₀ are all different classes of functional group (e.g., R₁ is a C₁-C₁₅ alkyl, R₂ is a C₂-C₁₅ amine, R₃ is a C₁-C₁₅ ether, R₄ is a C₁-C₁₅ fluoroether, R₅ is H, etc.). In some embodiments, at least one of R₁-R₁₀ are the same class of functional group (e.g., R₁-R₅ are C₁-C₁₅ alkyl and R₆-R₁₀ are a C₁-C₁₅ fluoroalkyl).

In some embodiments, for Formula 5, L₁ and L₂ are C₂-C₁₅ amide containing at least one fluoro group (e.g., bis(2,2,2-trifluoroethyl)amido). For example, Formula 6 represents the compound for when R₁-R₁₀ are H and L₁ and L₂ are bis(2,2,2-trifluoroethyl)amido represented by structural formula 5, as shown below:

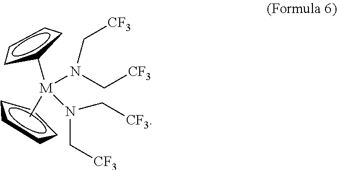

In some embodiments, for Formula 5, R₁-R₁₀ are H.

In some embodiments, for Formula 5, L₁ and L₂ are a C₁-C₁₅ alkoxide containing at least one fluoro group (e.g., 2,2,3,3,4,4,4-Heptafluoro-1-butoxide, 1,1,1,3,3,3-hexafluoro-2-propoxide, or 2,2,2-trifluoroethoxide. In some embodiments, for Formula 5, R₁-R₁₀ are H, and L₁ and L₂ are 2,2,3,3,4,4,4-Heptafluoro-1-butoxide. In some embodiments, for Formula 5, R₁-R₁₀ are H, and L₁ and L₂ are 1,1,1,3,3,3-hexafluoro-2-propoxide. In some embodiments, for Formula 5, R₁-R₁₀ are H, and L₁ and L₂ are 2,2,2-trifluoroethoxide.

For example, Formula 7 represents the compound for when R₁-R₁₀ are H and L₁ and L₂ are 2,2,3,3,4,4,4-heptafluoro-1-butoxide for Formula 5, as shown below: represented by structural formula 7:

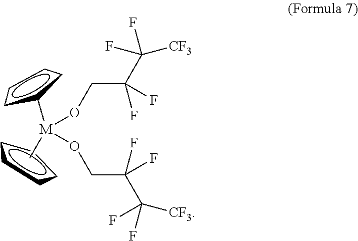

In some embodiments, for Formula 5, L₁ and L₂ are C₂-C₁₅ carboxylate containing at least one fluoro group (e.g., trifluoroacetate).

In some embodiments, the compound of the present disclosure comprises a compound with the following formula:

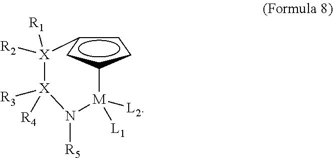

In some embodiments, for Formula 8, M is titanium (Ti), zirconium (Zr), or hafnium (Hf).

In some embodiments, for Formula 8, L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F.

In some embodiments, for Formula 8, L₂ is an alkyl, amide, alkoxide, carboxylate, amidinate, guanidinate, β-diketonate, β-ketoiminate, β-diketiminate, fluoroalkyl, alkoxide containing at least one fluoro group, amide containing at least one fluoro group, carboxylate containing at least one fluoro group, F, Cl, Br, I, or H. In some embodiments, for Formula 8, L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

In some embodiments, for Formula 8, L₁ and L₂ are the same class of ligand (e.g., C₁-C₁₅ alkyl) or the same ligand (e.g., methyl). In some embodiments, L₁ and L₂ are the same class of ligand (e.g., C₁-C₁₅ alkyl) but different ligands (e.g., L₁ is methyl and L₂ is ethyl). In some embodiments, L₁ and L₂ are all different classes of ligand (e.g., L₁ is a C₁-C₁₅ alkyl and L₂ is a C₂-C₁₅ amide).

In some embodiments, for Formula 8, X are each independently C or Si. In some embodiments, for Formula 8, both Xs are C or Si. In some embodiments, for Formula 8, one X is C and one X is Si.

In some embodiments, for Formula 8, R₁-R₅ are each independently a C₁-C₁₅ alkyl, C₁-C₁₅ fluoroalkyl, or H.

In some embodiments, R₁-R₅ are the same class of functional group (e.g., C₁-C₁₅ alkyl) or the same functional group (e.g., methyl). In some embodiments, R₁-R₅ are the same class of functional group (e.g., C₁-C₁₅ alkyl) but different functional groups (e.g., R₁ is methyl, R₂ is ethyl, R₃ is propyl, R₄ is butyl, and R₅ is pentyl). In some embodiments, R₁-R₅ are all different classes of functional group (e.g., R₁ is a C₁-C₁₅ alkyl, R₂ is a C₂-C₁₅ amine, R₃ is a C₁-C₁₅ ether, R₄ is a C₁-C₁₅ fluoroether, and R₅ is H). In some embodiments, at least one of R₁-R₅ are the same class of functional group (e.g., R₁ and R₂ are C₁-C₁₅ alkyl and R₃-R₅ is a C₁-C₁₅ fluoroalkyl).

In some embodiments, for Formula 8, X are C, R₁-R₄ are H, and R₅ is a methyl.

In some embodiments, for Formula 8, L₁ and L₂ are C₂-C₁₅ amide containing at least one fluoro group (e.g., bis(2,2,2-trifluoroethyl)amido). In some embodiments, for Formula 8, X are C, R₁-R₄ are H, R₅ is a methyl, and L₁ and L₂ are bis(2,2,2-trifluoroethyl)amido.

In some embodiments, for Formula 8, L₁ and L₂ are a C₁-C₁₅ alkoxide containing at least one fluoro group (e.g., 2,2,3,3,4,4,4-Heptafluoro-1-butoxide, 1,1,1,3,3,3-hexafluoro-2-propoxide, or 2,2,2-trifluoroethoxide).

In some embodiments, for Formula 8, L₁ and L₂ are L₁ and L₂ are a C₂-C₁₅ carboxylate containing at least one fluoro group (e.g., trifluoroacetate).

In some embodiments, the compound of the present disclosure comprises a compound with the following formula:

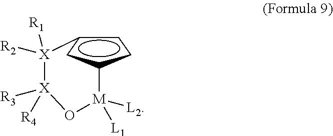

In some embodiments, for Formula 9, M is titanium (Ti), zirconium (Zr), or hafnium (Hf).

In some embodiments, for Formula 9, L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F.

In some embodiments, for Formula 9, L₂ is an alkyl, amide, alkoxide, carboxylate, amidinate, guanidinate, β-diketonate, β-ketoiminate, β-diketiminate, fluoroalkyl, alkoxide containing at least one fluoro group, amide containing at least one fluoro group, carboxylate containing at least one fluoro group, F, Cl, Br, I, or H. In some embodiments, for Formula 9, L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

In some embodiments, for Formula 9, L₁ and L₂ are the same class of ligand (e.g., C₁-C₁₅ alkyl) or the same ligand (e.g., methyl). In some embodiments, L₁ and L₂ are the same class of ligand (e.g., C₁-C₁₅ alkyl) but different ligands (e.g., L₁ is methyl and L₂ is ethyl). In some embodiments, L₁ and L₂ are all different classes of ligand (e.g., L₁ is a C₁-C₁₅ alkyl and L₂ is a C₂-C₁₅ amide).

In some embodiments, for Formula 9, X are each independently C or Si. In some embodiments, for Formula 9, both Xs are C or Si. In some embodiments, for Formula 8, one X is C and one X is Si.

In some embodiments, for Formula 9, R₁-R₄ are each independently a C₁-C₁₅ alkyl, C₁-C₁₅ fluoroalkyl, or H.

In some embodiments, for Formula 9, X are C, R₁-R₃ are H, and R₄ is a methyl.

In some embodiments, for Formula 9, L₁ and L₂ are a C₂-C₁₅ amide containing at least one fluoro group (e.g., bis(2,2,2-trifluoroethyl)amido). In some embodiments, for Formula 9, X are C, R₁-R₃ are H, R₄ is a methyl, and L₁ and L₂ are bis(2,2,2-trifluoroethyl)amido.

In some embodiments, for Formula 9, L₁ and L₂ are a C₂-C₁₅ carboxylate containing at least one fluoro group (e.g., trifluoroacetate). In some embodiments, for Formula 9, X are C, R₁-R₃ are H, R₄ is a methyl, and L₁ and L₂ are trifluoroacetate.

In some embodiments, for Formula 9, L₁ and L₂ are a C₁-C₁₅ alkoxide containing at least one fluoro group (e.g., 2,2,3,3,4,4,4-Heptafluoro-1-butoxide, 1,1,1,3,3,3-hexafluoro-2-propoxide, or 2,2,2-trifluoroethoxide). In some embodiments, for Formula 9, X are C, R₁-R₃ are H, R₄ is a methyl, and L₁ and L₂ are 2,2,3,3,4,4,4-Heptafluoro-1-butoxide, 1,1,1,3,3,3-hexafluoro-2-propoxide, or 2,2,2-trifluoroethoxide.

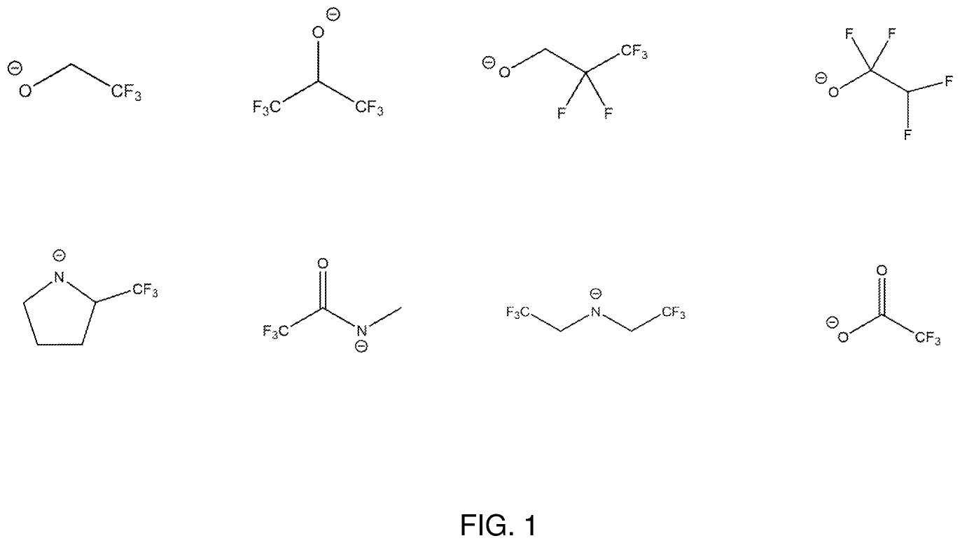

FIG. 1 displays fluorinated ligand compounds (fluorinated L groups (e.g., L₁, L₂, L₃, and L₄) for Formula 1-Formula 9) according to the present disclosure, in accordance with some embodiments.

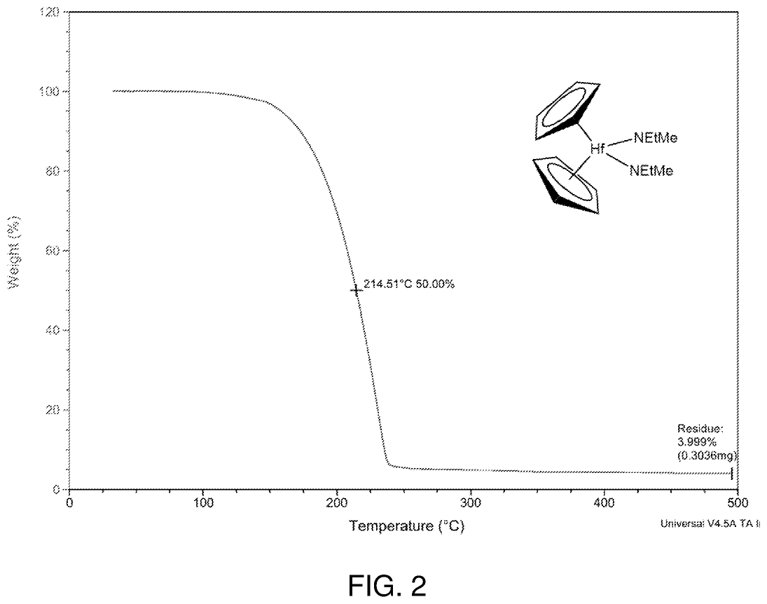

As a comparative example for fluorinated and nonfluorinated compounds, FIG. 2 displays thermogravimetric analysis (TGA) of a nonfluorinated compound: bis(cyclopentadienyl)Hf(NEtMe)₂.

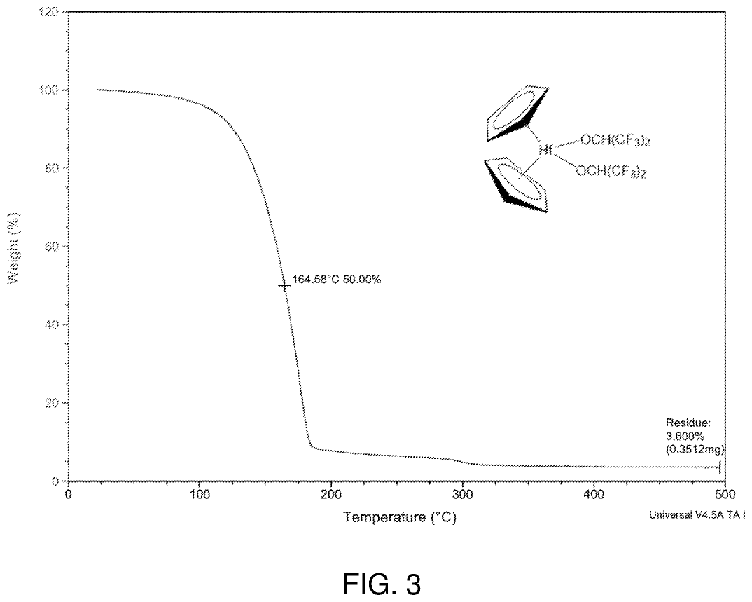

FIG. 3 displays TGA of bis(cyclopentadienyl)Hf(OCH(CF₃)₂)₂, in accordance with some embodiments.

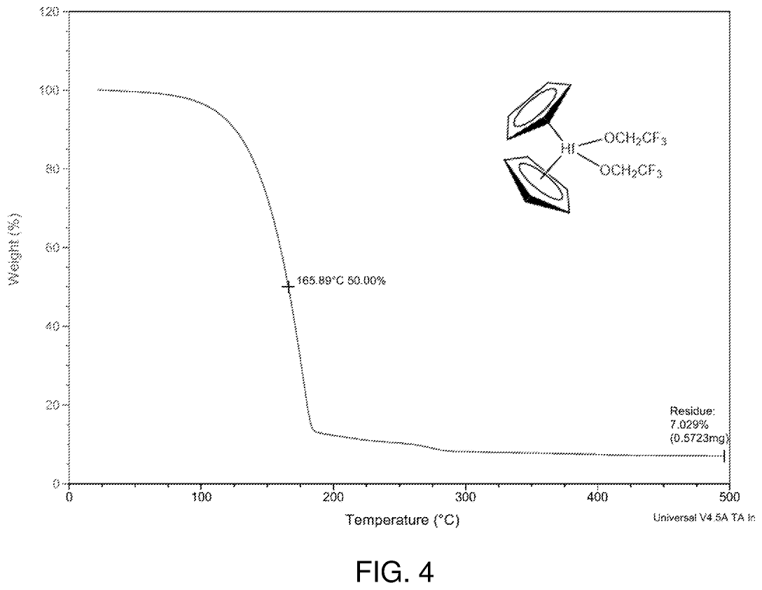

FIG. 4 displays TGA of bis(cyclopentadienyl)Hf(OCH₂CF₃)₂, in accordance with some embodiments.

ASPECTS

Various Aspects are described below. It is to be understood that any one or more of the features recited in the following Aspect(s) can be combined with any one or more other Aspect(s).

Aspect 1. A compound comprising the following formula:

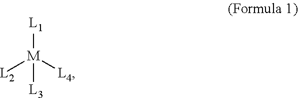

wherein: M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; and L₂-L₄ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

Aspect 2. The compound of Aspect 1, wherein the compound has the following formula:

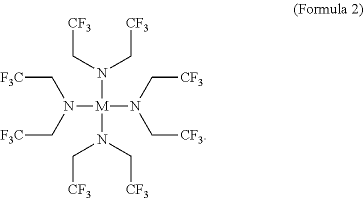

Aspect 3. The compound of Aspect 1, wherein L₁-L₄ are each independently 1,1,1,3,3,3-hexafluoro-2-propoxide, 2,2,3,3,4,4,4-Heptafluoro-1-butoxide, or 2,2,2-trifluoroethoxide.

Aspect 4. The compound of Aspect 1, wherein L₁-L₄ are trifluoroacetate.

Aspect 5. A compound comprising the following formula:

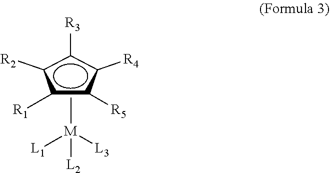

wherein: M is Ti, Zr, or Hf; L₁ is a C₁-C₁₅ fluoroalkyl, C₂-C₁₅ amide containing at least one fluoro group, C₂-C₁₅ carboxylate containing at least one fluoro group, or F; L₂ and L₃ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and R₁-R₅ are each independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H.

Aspect 6. The compound of claim 5, the compound has the following formula:

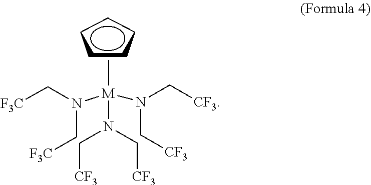

Aspect 7. The compound of Aspect 5, wherein R₁-R₅ are H.

Aspect 8. The compound of Aspect 5 or Aspect 6, wherein L₁-L₃ are 1,1,1,3,3,3-hexafluoro-2-propoxide, 2,2,3,3,4,4,4-heptafluoro-1-butoxide, 2,2,2-trifluoroethoxide.

Aspect 9. The compound of Aspect 5 or Aspect 6, wherein L₁-L₃ are trifluoroacetate.

Aspect 10. A compound comprising the following formula:

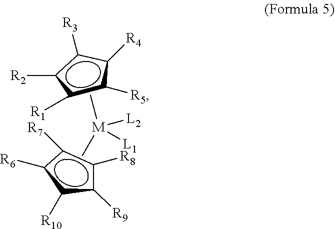

wherein: M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and R₁-R₁₀ are each independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H.

Aspect 11. The compound of Aspect 10, wherein the compound has the following formula:

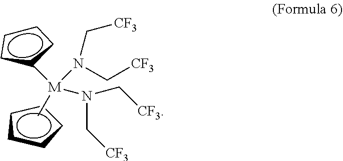

Aspect 12. The compound of Aspect 10, wherein R₁-R₁₀ are H.

Aspect 13. The compound of Aspect 10 or Aspect 12, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

Aspect 14. The compound of Aspect 10, wherein the compound has the following formula:

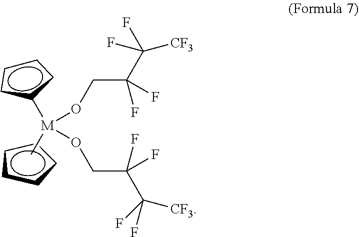

Aspect 15. The compound of Aspect 10 or Aspect 12, wherein L₁ and L₂ are 2,2,2-trifluoroethoxide.

Aspect 16. A compound comprising the following formula:

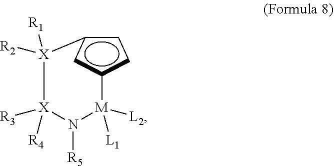

wherein: M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; X are each independently C or Si; and R₁-R₅ are each independently a C₁-C₁₅ alkyl, C₁-C₁₅ fluoroalkyl, or H.

Aspect 17. The compound of Aspect 16, wherein X are C, R₁-R₄ are H, and R₅ is a methyl.

Aspect 18. The compound of Aspect 16 or Aspect 17, wherein L₁ and L₂ are bis(2,2,2-trifluoroethyl)amido.

Aspect 19. The compound of Aspect 16 or Aspect 17, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

Aspect 20. The compound of Aspect 16 or Aspect 17, wherein L₁ and L₂ are trifluoroacetate.

Aspect 21. A compound comprising the following formula:

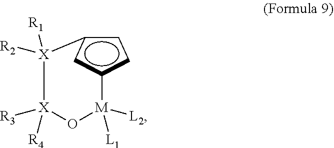

wherein: M is Ti, Zr, or Hf; L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; X are each independently C or Si; and R₁-R₄ are each independently a C₁-C₁₅ alkyl, C₁-C₁₅ fluoroalkyl, or H.

Aspect 22. The compound of Aspect 21, wherein X are C, R₁-R₃ are H, and R₄ is a methyl.

Aspect 23. The compound of Aspect 21 or Aspect 22, wherein L₁ and L₂ are bis(2,2,2-trifluoroethyl)amido.

Aspect 24. The compound of Aspect 21 or Aspect 22, wherein L₁ and L₂ are trifluoroacetate.

Aspect 25. The compound of Aspect 21 or Aspect 22, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A compound comprising the following formula:
wherein: 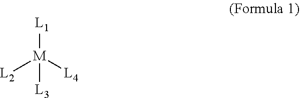
M is Ti, Zr, or Hf;
L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F; and
L₂-L₄ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H.

2. The compound of claim 1, wherein the compound has the following formula:

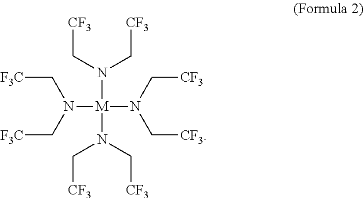

3. The compound of claim 1, wherein L₁-L₄ are each independently 1,1,1,3,3,3-hexafluoro-2-propoxide, 2,2,3,3,4,4,4-Heptafluoro-1-butoxide, or 2,2,2-trifluoroethoxide.

4. The compound of claim 1, wherein L₁-L₄ are trifluoroacetate.

5. A compound comprising the following formula:
wherein: 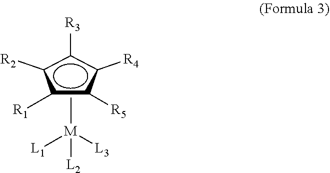
M is Ti, Zr, or Hf;
L₁ is a C₁-C₁₅ fluoroalkyl, C₂-C₁₅ amide containing at least one fluoro group, C₂-Cis carboxylate containing at least one fluoro group, or F;
L₂ and L₃ are each independently a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and
R₁-R₅ are each independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H.

6. The compound of claim 5, the compound has the following formula:

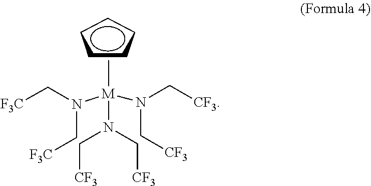

7. The compound of claim 5, wherein R₁-R₅ are H.

8. The compound of claim 5, wherein L₁-L₃ are 1,1,1,3,3,3-hexafluoro-2-propoxide, 2,2,3,3,4,4,4-heptafluoro-1-butoxide, 2,2,2-trifluoroethoxide.

9. The compound of claim 5, wherein L₁-L₃ are trifluoroacetate.

10. A compound comprising the following formula: 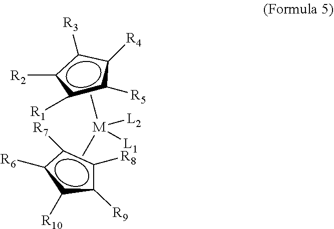
wherein:
M is Ti, Zr, or Hf;
L₁ is a C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, or F;
L₂ is a C₁-C₁₅ alkyl, C₂-C₁₅ amide, C₁-C₁₅ alkoxide, C₁-C₁₅ carboxylate, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, C₂-C₁₅ carboxylate containing at least one fluoro group, F, Cl, Br, I, or H; and
R₁-R₁₀ are each independently a C₁-C₁₅ alkyl, C₁-C₁₅ ether, C₂-C₁₅ amine, C₁-Cis fluoroether, C₁-C₁₅ fluoroalkyl, OH, F, Cl, Br, I, or H.

11. The compound of claim 10, wherein the compound has the following formula:

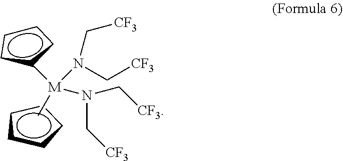

12. The compound of claim 10, wherein R₁-R₁₀ are H.

13. The compound of claim 10, wherein L₁ and L₂ are 2,2,3,3,4,4,4-Heptafluoro-1-butoxide, 1,1,1,3,3,3-hexafluoro-2-propoxide, 2,2,2-trifluoroethoxide, or combinations thereof.

14. The compound of claim 10, wherein the compound has the following formula:

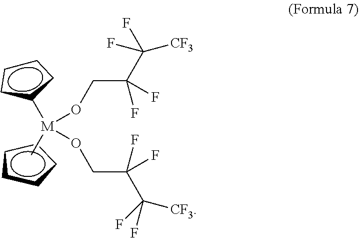

15. The compound of claim 10, wherein L₁ and L₂ are 2,2,2-trifluoroethoxide.
